(19) United States
(12) Patent Application Publication
(10) Pub. No.: US 2026/0251860 A1
(43) Pub. Date: Aug. 27, 2026

(54) DEVICE AND METHOD FOR EPOXY-FREE OPTICAL INTEGRATION IN PHOTONIC INTEGRATED CIRCUITS

(71) Applicant: MIXX TECHNOLOGIES, INC., San Jose, CA (US)

(72) Inventors: Rebecca Kayla Schaevitz, Sunnyvale, CA (US); Vivek Raghuraman, San Jose, CA (US); Qijun Xiao, Fremont, CA (US)

(73) Assignee: MIXX TECHNOLOGIES, INC., San Jose, CA (US)

(21) Appl. No.: 19/547,508

(22) Filed: Feb. 23, 2026

Related U.S. Application Data
(60) Provisional application No. 63/762,886, filed on Feb. 25, 2025.

(51) Int. Cl. G02B 6/42; H10W 90/20

(52) U.S. Cl. CPC G02B 6/4214; G02B 6/4207; G02B 6/4212; G02B 6/4239; H10W 90/297

(57) ABSTRACT

A method and assembly for forming a photonic integrated circuit (PIC) with epoxy-free hybrid bonding of optical and electronic components may be provided. The method may include providing a silicon wafer with a buried oxide layer, silicon waveguide, and backend metal layers, forming an opening to expose a nitride waveguide facet, and hybrid bonding a lower body reflector (LBR) within the opening. A handle silicon wafer may be attached, and a conformal oxide layer may be deposited and planarized. Through-dielectric vias (TDVs) or through-silicon vias (TSVs) may be formed for vertical electrical connectivity. An electronic integrated circuit (EIC) may be hybrid bonded over the oxide layer. The resulting PIC assembly may include the LBR and EIC bonded without epoxy, providing robust optical alignment, electrical interfacing, and thermal stability. The assembly may minimize air gaps to ensure optical continuity and may incorporate TDVs or TSVs for enhanced electrical integration.

### RELATED APPLICATION

This application claims the benefit of U.S. Provisional Application No. 63/762,886, filed February 25, 2025, the disclosure of which is incorporated herein by reference in its entirety for all purposes.

The examples discussed in the present disclosure are related to devices and methods for epoxy-free optical integration in photonic integrated circuits.

### BACKGROUND

Unless otherwise indicated herein, the materials described herein are not prior art to the claims in the present application and are not admitted to be prior art by inclusion in this section.

Photonic Integrated Circuits (PICs) may be components in high-speed telecommunications, data center networking, and advanced computing systems, where they enable high-bandwidth data transfer and efficient signal processing. Integration of optical components, such as lenses, mirrors, and waveguides, within PICs facilitate the precise transmission and manipulation of light signals to optical fiber. Epoxy may be used to bond these optical components to the silicon substrate or other structures within the PIC. Epoxy bonding may be applied in industry due to adhesive properties, ease of application, and capacity to form bonds in complex geometries, allowing for flexibility in design and assembly. Epoxy can also be transparent to light and thus not impede the light transmission while bonding these components in place.

In some integrations, epoxy may be used to affix optical elements such as lenses or mirrors to the PIC substrate. For example, epoxy may be applied directly to a silicon waveguide to secure a fiber optic interface, or to adhere mirrors and lenses that redirect or reshape light within the PIC. This approach may simplify assembly by allowing optical components to be bonded to the substrate with minimal additional processing operations. However, epoxy-based integration faces significant limitations, especially as PIC technology advances and demands for thermal resilience, high optical powers, and optical efficiency increase.

For example, epoxy may be susceptible to high temperatures. Many PIC assembly processes used for joint electron device engineering council (JEDEC) compliance and high-throughput production, involve elevated temperatures—often exceeding 260°C. Epoxy degrades under these conditions, leading to potential softening, outgassing, yellowing, and misalignment of components. This thermal instability restricts epoxy’s applicability in high-temperature manufacturing processes such as solder reflow, which often uses temperatures around >200°C to achieve the throughput quality. Epoxy’s thermal limitations also present challenges in environments where PICs may experience repeated thermal cycling, potentially resulting in device failure over time.

As another example, epoxy may be susceptible to high optical powers. In PIC systems, often the laser may be an external power source for the transmit channel. In this configuration, the laser may typically support 4-8 transmit channels through high power greater than 100mW. Optical epoxies typically start to yellow and degrade over time, reducing their transparency and increasing loss, making it an unreliable choice for many PIC solutions.

The subject matter claimed in the present disclosure is not limited to examples that solve any disadvantages or that operate only in environments such as those described above. Rather, this background is only provided to illustrate one example technology area where some examples described in the present disclosure may be practiced.

### SUMMARY

The examples herein present a device and method for integrating optical elements within Photonic Integrated Circuits (PICs) without the use of epoxy, addressing limitations of epoxy-based bonding methods. In some examples, a method for integrating optical elements in Photonic Integrated Circuits (PICs) using an epoxy-free implementation may be configured for high-temperature compatibility and precise alignment. In some examples, the process begins with etching a silicon wafer to create a cavity with angled sidewalls, configured by the wafer's crystallographic orientation. A high-reflectivity (HR) coating may be deposited on at least one sidewall of the cavity to form a reflective surface, which may be configured for directing or reshaping light within the PIC.

In some examples, subsequent to the creation of the reflective surface, a thermal oxide layer may be grown over the exposed surfaces of the wafer, including within the angled cavity, to a uniform thickness. In some examples, an additional oxide layer may be deposited and planarized to create a flat bonding surface. Such oxide layer may serve as a foundation for the hybrid bonding of optical components, providing a stable and uniform surface without using polishing.

In some examples, which use electrical connectivity, through-dielectric vias (TDVs) may be positioned within the oxide layer by etching and filling holes with conductive material. In some examples, further structural stability or added thickness may be provided via an additional silicon wafer, which may be bonded to the planarized oxide surface. In some examples, such wafer includes blind through-silicon vias (TSVs) that, after backside thinning and metallization, complete the electrical connections for advanced PIC configurations through hybrid bonding. The structure may be flipped, and the original silicon wafer may be selectively etched away, providing a high-quality oxide surface with embedded optical and electrical pathways ready for integration within a PIC.

The objects and advantages of the examples will be realized and achieved at least by the elements, features, and combinations particularly pointed out in the claims.

Both the foregoing general description and the following detailed description are given as examples and are explanatory and are not restrictive of the invention, as claimed.

### BRIEF DESCRIPTION OF THE DRAWINGS

So that the manner in which the above recited features of the present disclosure can be understood in detail, a more particular description of the disclosure, briefly summarized above, may be had by reference to examples, some of which are illustrated in the appended drawings. It is noted, however, that the appended drawings illustrate only some aspects of this disclosure and the disclosure may admit to other equally effective examples.

To facilitate understanding, identical reference numerals have been used, where possible, to designate identical elements that are common to the figures. It is contemplated that elements and features of one example may be beneficially incorporated in other examples without further recitation.

FIGS. 1A-1J are schematics of an exemplary method for fabricating an optical device configured for hybrid bonding, in accordance with some examples;

FIGS. 2A-2I are schematics of an exemplary method for fabricating an optical device configured for hybrid bonding, in accordance with some examples; and

FIGS. 3A-3G are schematics of an exemplary method for fabricating an optical device configured for hybrid bonding, in accordance with some examples.

### DETAILED DESCRIPTION

The present disclosure will now be described in detail with reference to the drawings, which are provided as illustrative examples of the disclosure so as to enable those skilled in the art to practice the disclosure. Notably, the figures and examples below are not meant to limit the scope of the present disclosure to a single example, but other examples are possible by way of interchange of some or all of the described or illustrated elements. Moreover, where certain elements of the present disclosure can be partially or fully implemented using known components, only those portions of such known components that are necessary for an understanding of the present disclosure will be described, and detailed descriptions of other portions of such known components will be omitted so as not to obscure the disclosure.

As used herein, the singular form of “a”, “an”, and “the” include plural references unless the context clearly dictates otherwise. As used herein, the statement that two or more parts or components are “coupled” shall mean that the parts are joined or operate together either directly or indirectly (i.e., through one or more intermediate parts or components, so long as a link occurs). As used herein, “directly coupled” means that two elements are directly in contact with each other. As used herein, “fixedly coupled” or “fixed” means that two components are coupled so as to move as one while maintaining a constant orientation relative to each other. As used herein, “operatively coupled” means that two elements are coupled in such a way that the two elements function together. It is to be understood that two elements “operatively coupled” does not require a direct connection or a permanent connection between them. As utilized herein, “substantially” means that any difference is negligible, or that such differences are within an operating tolerance that are known to persons of ordinary skill in the art and provide for the performance and outcomes as described in one or more examples herein. Descriptions of numerical ranges are endpoints inclusive.

As used herein, the word “unitary” means a component is created as a single piece or unit. That is, a component that includes pieces that are created separately and then coupled together as a unit is not a “unitary” component or body. As employed herein, the statement that two or more parts or components “engage” one another shall mean that the parts exert a force against one another either directly or through one or more intermediate parts or components. As employed herein, the term “number” shall mean one or an integer greater than one (i.e., a plurality). Directional phrases used herein, such as, for example and without limitation, top, bottom, left, right, upper, lower, front, back, and derivatives thereof, relate to the orientation of the elements shown in the drawings and are not limiting upon the claims unless expressly recited therein.

Examples described as being implemented in hardware should not be limited thereto, but can include examples implemented in software, or combinations of software and hardware, and vice-versa, as will be apparent to those skilled in the art, unless otherwise specified herein. In the exemplary examples described herein, an example showing a singular component should not be considered limiting; rather, the disclosure is intended to encompass other examples including a plurality of the same component, and vice-versa, unless explicitly stated otherwise herein. Moreover, applicants do not intend for any term in the specification or claims to be ascribed an uncommon or special meaning unless explicitly set forth as such. Further, the present disclosure encompasses present and future known equivalents to the known components referred to herein by way of illustration.

The examples described below present a groundbreaking advancement in photonic integration by enabling epoxy-free bonding solutions that significantly enhance performance and scalability for high-temperature, high-throughput applications. Traditional photonic integration methods have relied heavily on epoxy to bond optical components like mirrors, lenses, and waveguides. Yet epoxy cannot withstand the high temperatures used in advanced manufacturing processes such as solder reflow, where temperatures often exceed 200°C. Additionally, epoxy in the optical path can degrade over time, leading to misalignment, increased insertion loss, and unwanted reflections that compromise signal quality within the PIC.

Additionally, epoxy's presence in the optical path can interfere with optical performance. The refractive index mismatch between epoxy and photonic integrated circuit (PIC) waveguides can create back reflections, leading to higher insertion loss and signal degradation. Air gaps or voids in the epoxy can exacerbate these issues, causing unwanted reflections and increasing insertion loss, which negatively affects the overall efficiency and reliability of the PIC. Furthermore, epoxy-based bonding restricts post-processing capabilities, limiting manufacturers' flexibility to modify or enhance optical elements once the epoxy has been applied. Lastly, epoxy can degrade with high optical powers and can limit performance of the system.

Accordingly, the epoxy-free approach of the examples herein leverages hybrid or fusion bonding techniques, which not only eliminate the temperature limitations of epoxy but also ensure a stable, precise wafer-scale alignment advantageous for advanced Photonic Integrated Circuits (PICs) used in telecommunications, data center networking, and high-speed computing. Discussed in detail below, the examples herein enable integration of reflectors, minimizes insertion loss, and reduces reflections that degrade signal quality. Additionally, these examples support high-throughput manufacturing, making such examples scalable for commercial production. Thus, the examples described below include processes and devices enhance the efficiency, stability, and optical integrity of PICs, meeting modern high-performance photonic applications.

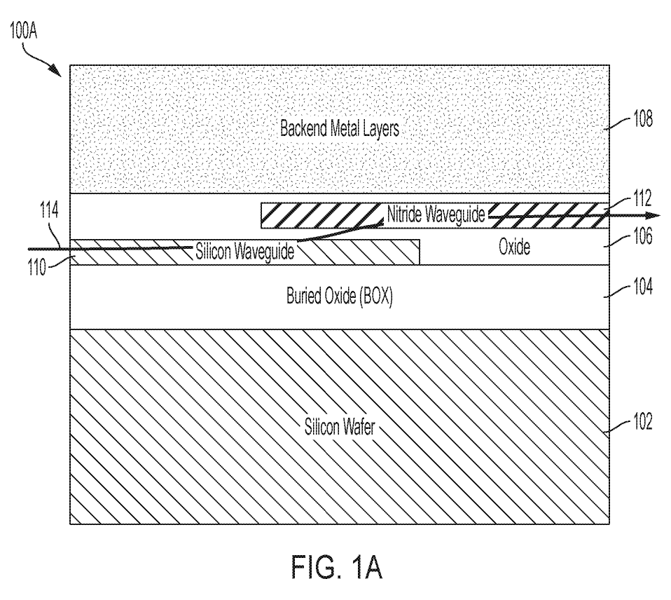

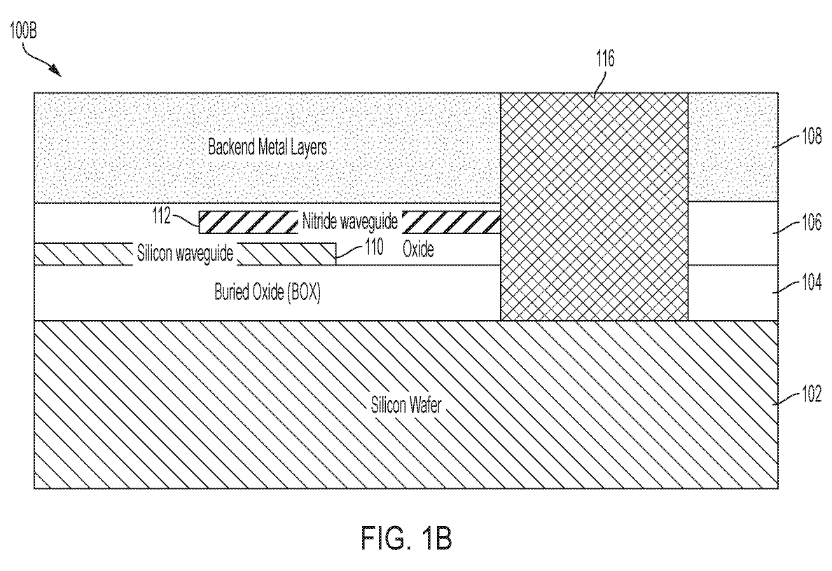

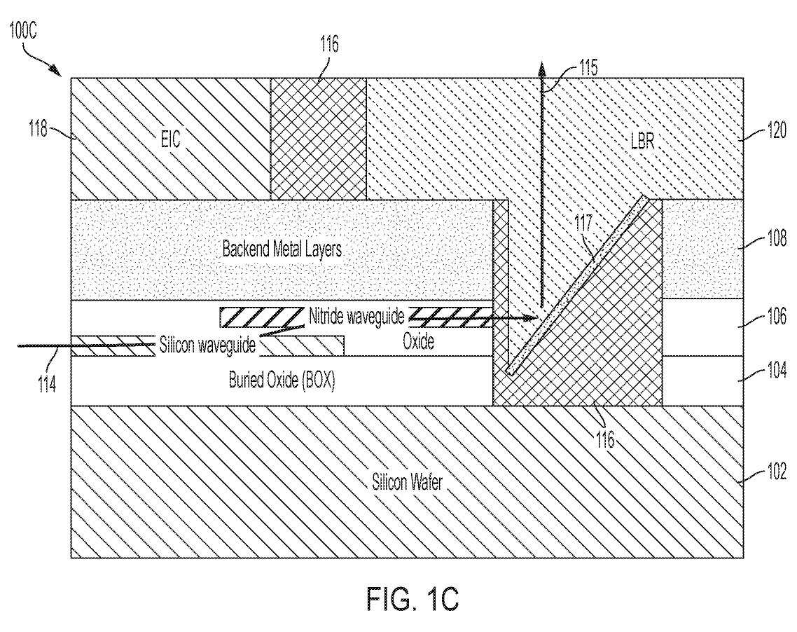

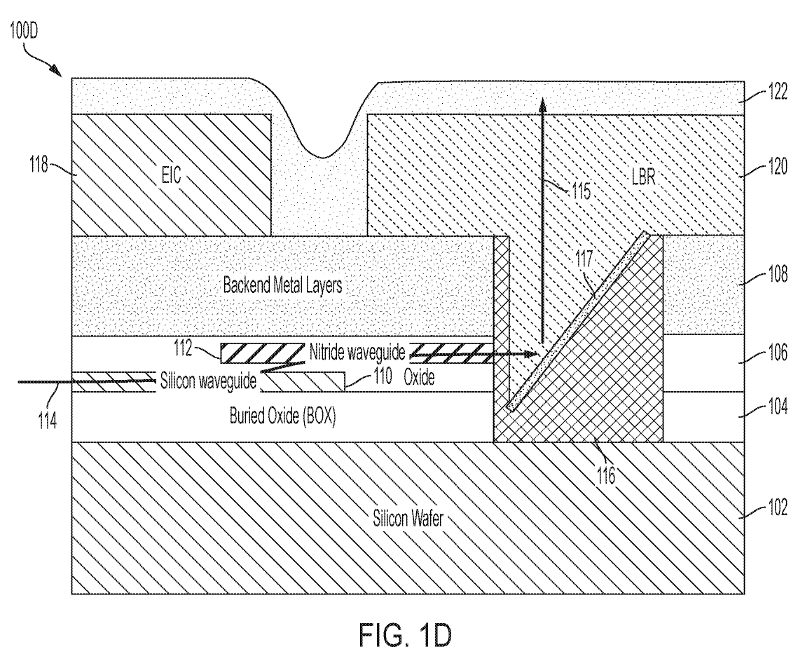

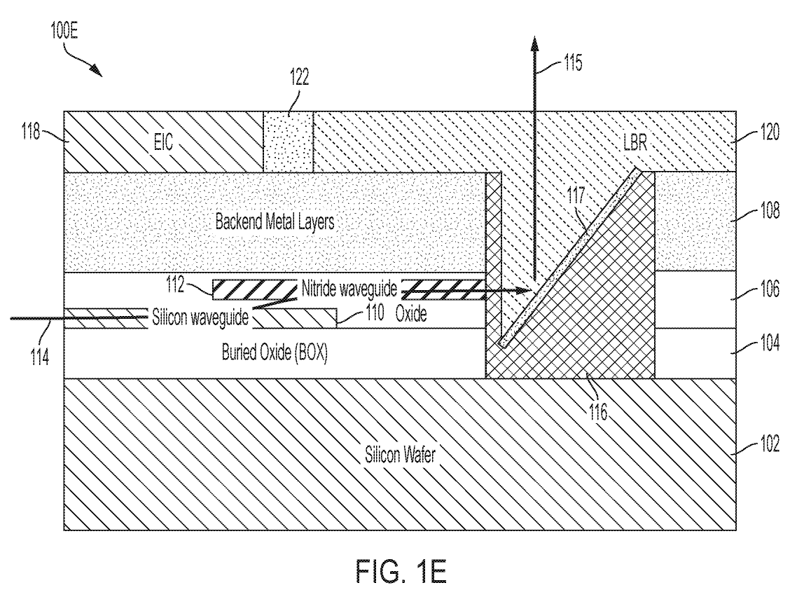

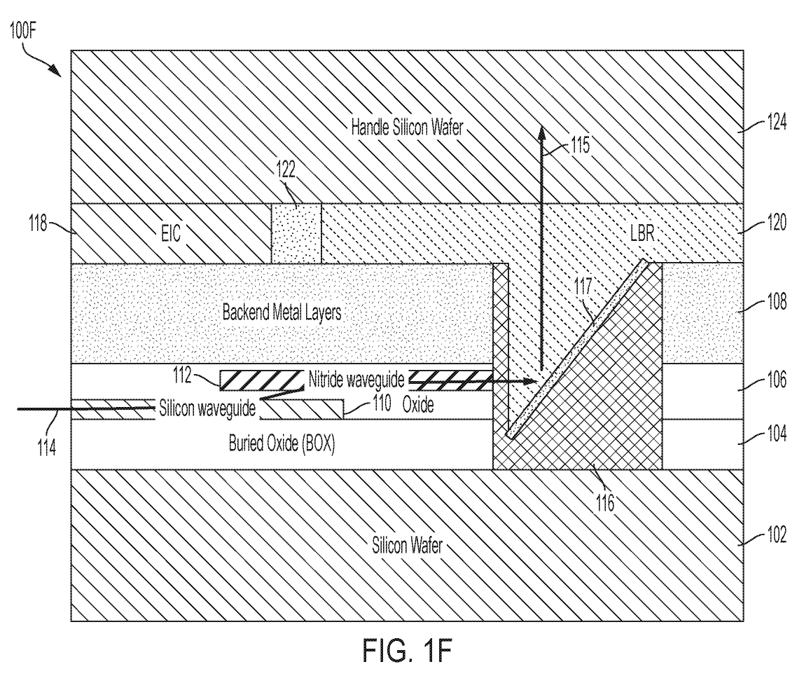

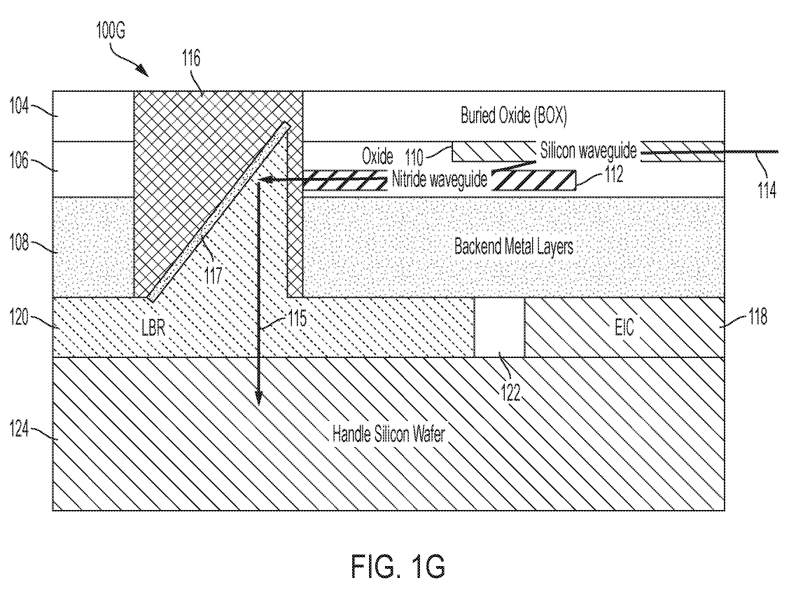

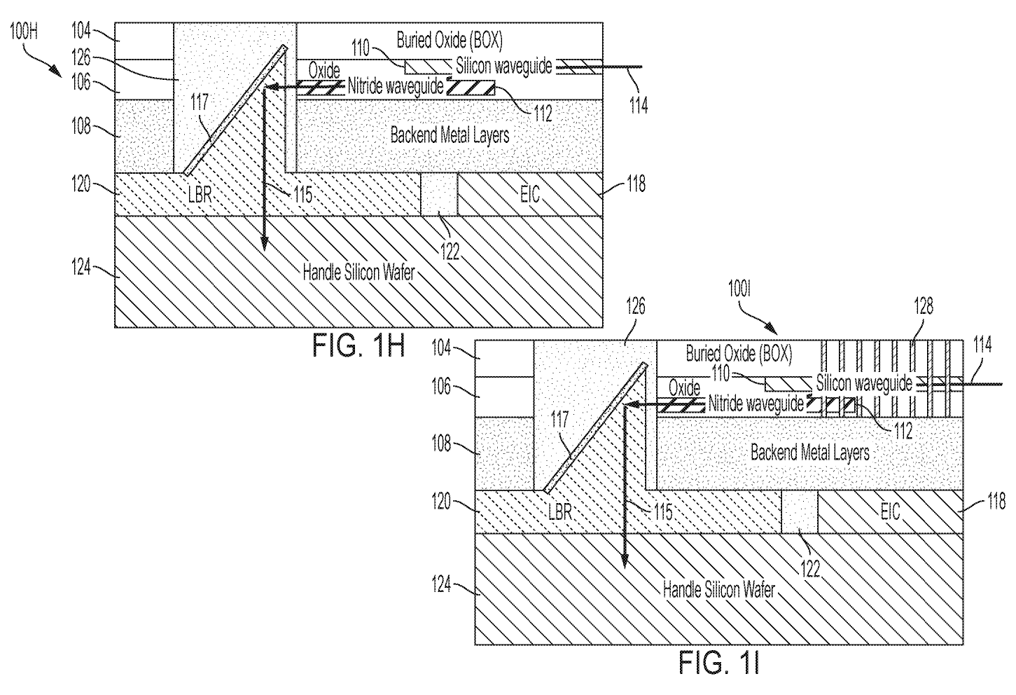

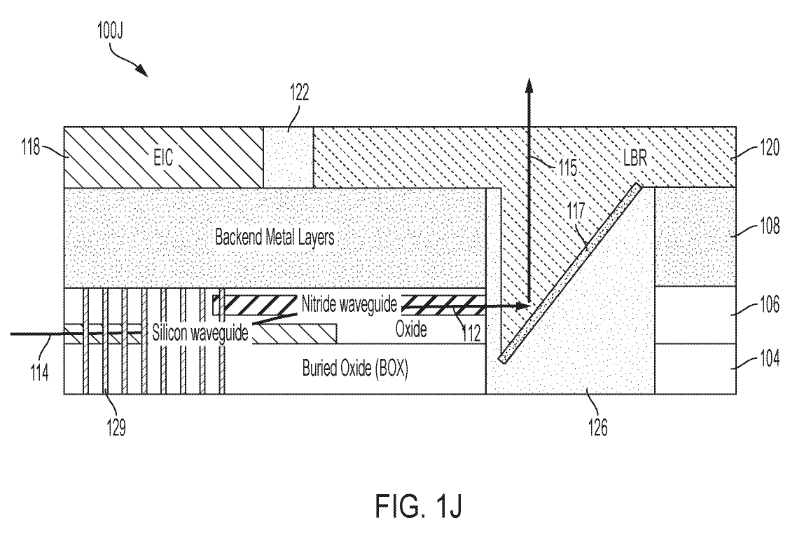

Referring to FIGS. 1A-1I, FIGS. 1A-1I depicts a method corresponding to epoxy-free optical integration for a PIC assembly. For example, such method may begin with optical structure 100A. Optical structure 100A may include stacked layers including silicon wafer 102, buried oxide (BOX) 104, Oxide 106, and Backend Metal Layers 108. Oxide layer 106 may include silicon waveguide 110 and/or nitride waveguide 112, which may be configured to propagate an optical signal 114.

FIG. 1A illustrates a photonic integrated circuit (PIC) structure 100A. In structure 100A silicon wafer 102 serves as the substrate for various photonic layers. A buried oxide (BOX) layer 104 separates the silicon wafer 102 from the active photonic components. Above the BOX layer 104, a silicon waveguide 110 and a nitride waveguide 112 (optional) may be embedded within an oxide layer 106. While the nitride waveguide is optional, such configuration may facilitate higher optical powers compared to other examples without nitride waveguide 112. Having the capability for higher optical powers may be advantageous in PIC and system design. Additionally, transferring light to a higher layer away from the silicon wafer 102, independent of the waveguide material, can enable a larger mode expansion without loss, typically up to 4-6um or larger. A larger mode may be beneficial to reduce loss associated with misalignment and to better couple into fiber, which typically has approximately a 9um mode size. The transition of the optical path from the silicon waveguide 110 to the nitride waveguide 112 may be achieved through evanescent coupling, allowing for gradual alignment and efficient light transfer. Backend metal layers 108 may be positioned above the nitride waveguide 112, providing connectivity for additional electronic components and interconnects.

As shown in FIG. 1B, in the examples herein, structure 100A may be modified to incorporate an epoxy-free approach for integrating optical elements. For example, in structure 100B, a cavity 116 may be etched down through the backend metal layers 108, oxide layer 106, and BOX layer 104 to reach the silicon wafer 102. Cavity 116 may be created through processes such as deep reactive ion etching (DRIE) or other etching techniques and may stop at the silicon wafer or may etch into the silicon wafer. Cavity 116 may provide a designated area for the integration of optical components without the use of epoxy, facilitating more robust post-processing and allowing for high-temperature processes like solder reflow. Cavity 116 may be strategically located where the waveguide exits, whether it is a silicon waveguide 110 or nitride waveguide 112, optimizing space and preserving structural integrity in other areas of structure 100B.

In FIG. 1C, a lower body reflector (LBR) 120 and an electronic integrated circuit (EIC) 118 may be integrated into structure 100C through hybrid bonding. LBR 120, which may have an etched angled surface 117 for redirecting the light, may be positioned adjacent to the nitride waveguide 112 (or optionally the silicon waveguide 114) and may be hybrid or fusion bonded on top of the backend metal layers 108 across cavity 116 or the wafer. The angled surface of the LBR may help direct light from the silicon waveguide 110 through the nitride waveguide 112 to an external optical path 115. EIC 118 may be hybrid bonded to the backend metal layers 108 and may be configured to provide electrical components for structure 100C. This bonding may happen during the LBR integration stage or at a later time after the LBR is fully integrated at the wafer scale and the subsequent structure may be thinned to reveal the backend metal layers for hybrid bonding. Both the LBR 120 and EIC 118 may use a smooth, planar surface for hybrid bonding, which may be achieved through polishing and preparation of the bonding interface prior to assembly.

In FIG. 1D, an additional oxide layer 122 may be deposited conformally over the structure 100D, covering the LBR 120, EIC 118, and the backend metal layers 108. Such oxide layer 122 may fill remaining air gaps within the structure, such as between the LBR 120 and EIC 118 bonded above the backend metal layer 108 surface. The deposition of oxide may help to stabilize the structure or PIC assembly and minimize thermal cycling issues, which may occur during high-temperature processes.

FIG. 1E shows structure 100E, after a planarization operation that levels oxide layer 122, EIC 118 and LBR 120, creating a uniform, flat surface for additional processing. This planarized surface may be advantageous for adding through-dielectric vias (TDVs) or through-silicon vias (TSVs), which may be introduced in subsequent operations. Such uniform oxide layer 122 may provide a stable platform for further integration, ensuring compatibility with high-throughput manufacturing processes. Additionally, the uniform oxide layer may allow it to integrate into multi-die packaging solutions or allow for other subsequent wafer scale processes.

In FIG. 1F, a handle silicon wafer 124 may be bonded to the planarized oxide surface. Handle silicon wafer 124 may provide mechanical support to structure 100F, allowing for inversion of the assembly and the selective removal of the original silicon wafer 102. Such selective removal may be completed by methods such as tetramethylammonium hydroxide (TMAH) etching, which leaves the oxide-encased components, LBR 120 and cavity 116, exposed for further processing.

After inversion and removal of the original silicon wafer 102, as shown in FIG. 1G, reflective angled surface 117 and oxide-encased waveguide structure 100G may be fully revealed. Inversion and removal prepares the structure for the next operation of filling in the air gaps with oxide. FIG. 1H demonstrates structure 100H with an additional oxide layer 126 deposited conformally over the exposed reflective and waveguide regions. This additional oxide layer 126 further encapsulates the reflective surface 117 and the waveguides, providing both mechanical stability and protection from environmental influences. The additional oxide layer 126 may also act as an optical cladding that reduces unwanted reflections and maintains low insertion losses by closely matching the refractive index with adjacent layers.

As shown in FIG. 1H once the surface has been planarized to prepare such surface for subsequent operations (e.g., such as TDVs or TSVs or other hybrid bonding), structure 100H may enable precise alignment and light redirection via the LBR 120, without the use of epoxy, which would not withstand the high temperatures used for hybrid bonding or reflow. Additionally, air gaps have been filled that could cause a “popcorn” effect, limiting lifetime reliability over thermal cycling events. Lastly, oxide layer 126 may extend the BOX 104 region to enable oxide layer 126 to be thicker, which may be advantageous for larger mode sizes that otherwise would overlap with the original handle silicon and lead to significant optical loss. Larger mode sizes also enable easier alignment and lower optical loss, therefore improving the optical transmission properties, as well as reducing cost and improving yield in manufacturing.

In FIG. 1I, structure 100I incorporates TDVs 129 that extend through the oxide layers to establish electrical connectivity between the backend metal layers 108 and the external circuitry. TDVs 129 may be formed by etching holes through the oxide layers and filling the etched holes with a conductive material, such as metal. The TDVs 129 enable efficient signal, power and ground transmission while preserving the compact, layered structure for advanced PICs.

Referring now to FIG. 1J in conjunction with FIGS. 1A-1I, FIG. 1J illustrates PIC assembly 100J, which may be the configuration of the integrated optical and electrical structures described in FIGS. 1A-1H. As shown in FIG. 1J, TDVs 129 may provide robust electrical interconnects that can attach to bumps or other dies for further downstream packaging, while the LBR 120 with the angled reflective surface 117 may ensures precise light redirection and minimal signal loss. The nitride waveguide 112 may be effectively coupled to the optical path 115, optimized for seamless integration with external optical components. This final PIC assembly 100J, free from epoxy, may be stable, thermally resilient, and ideal for high-density photonic applications in environments using both optical and electrical functionalities.

One or more additional silicon layers incorporating through-silicon vias (TSVs), such as blind TSVs, may be introduced to further extend the overall thickness of the PIC assembly 100J. Such added silicon layer may be polished to an appropriate thickness to reveal the TSVs, maintaining the electrical connectivity to external components. Such an extension may provide enhanced mechanical robustness to the overall structure while preserving the compact electrical and optical integration.

As shown in FIG. 1J, PIC assembly 100J may achieve a thickness of approximately 10-50 microns, which may be advantageous for some applications. However, where greater structural rigidity or additional functional layers are used, the integration of a supplementary silicon layer with TSVs may be advantageous to bolster the assembly. Such additional layer may be integrated on the bottom of the assembly to provide further electrical pathways or on the top, complementing the optical path with structural or functional enhancements, such as lenses and other turning elements. The flexibility to incorporate such layers ensures that the PIC assembly may be tailored to meet the demands of various high-performance applications while retaining its epoxy-free construction and high thermal resilience.

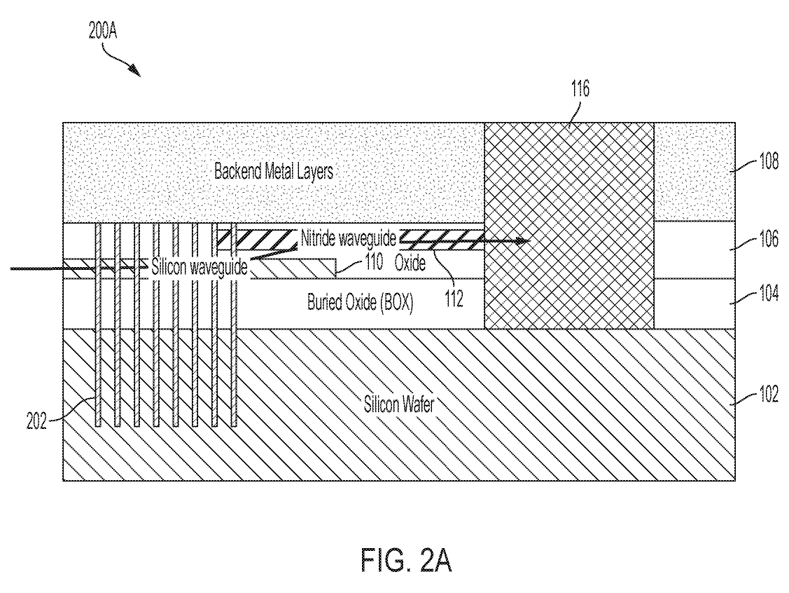

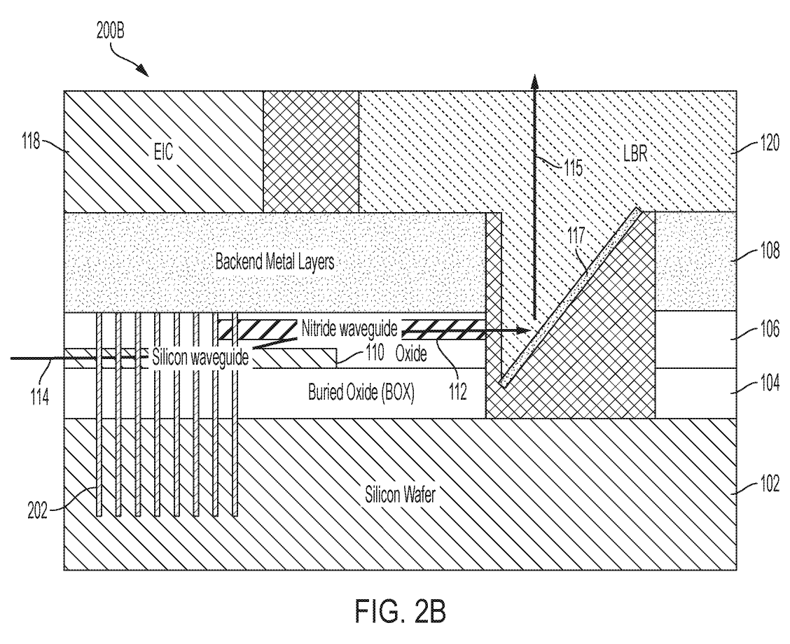

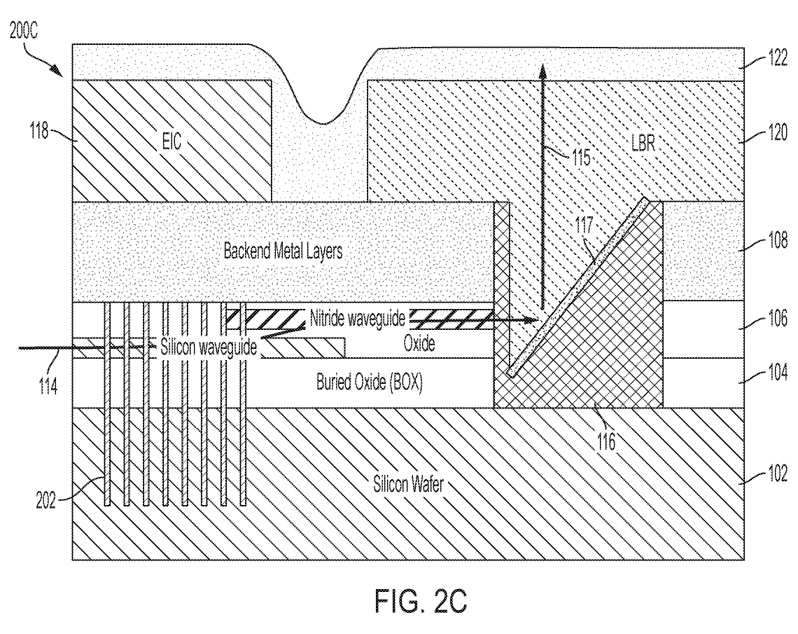

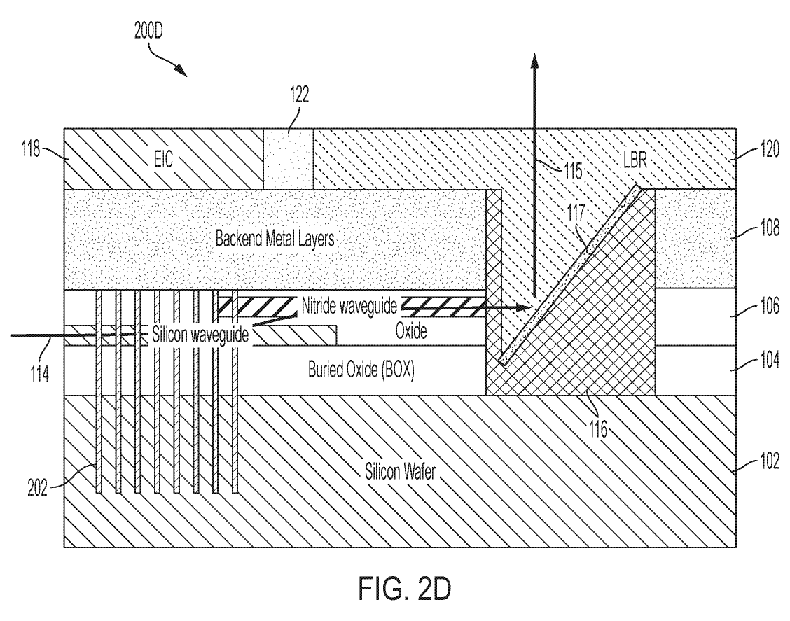

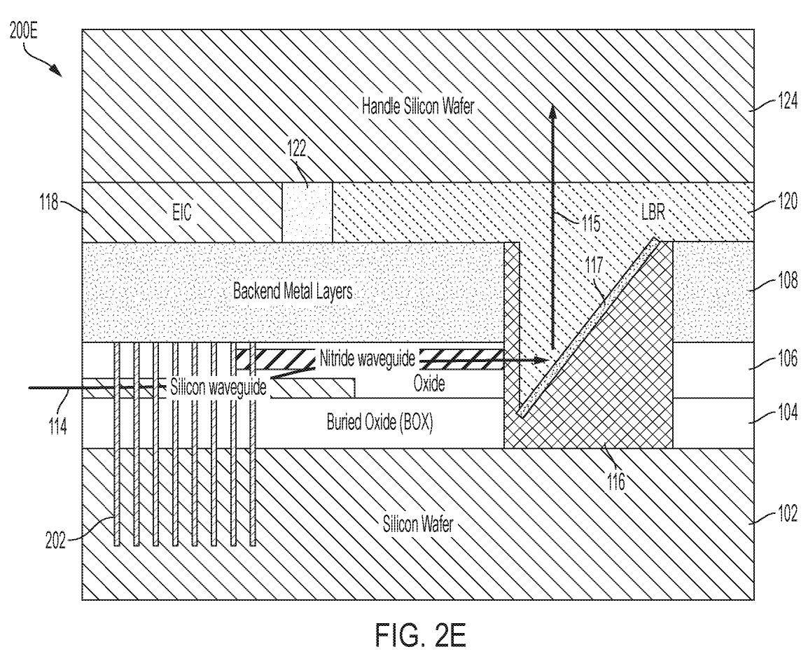

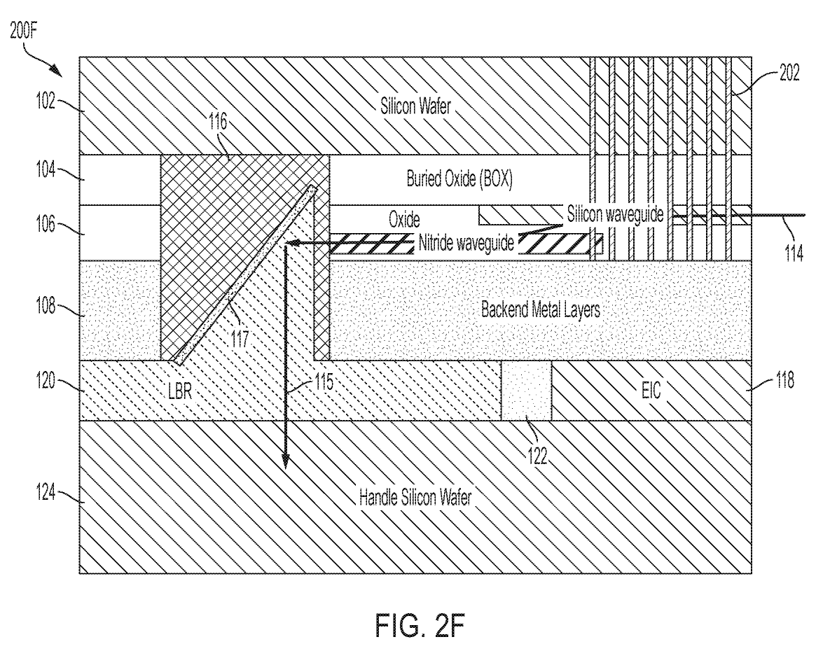

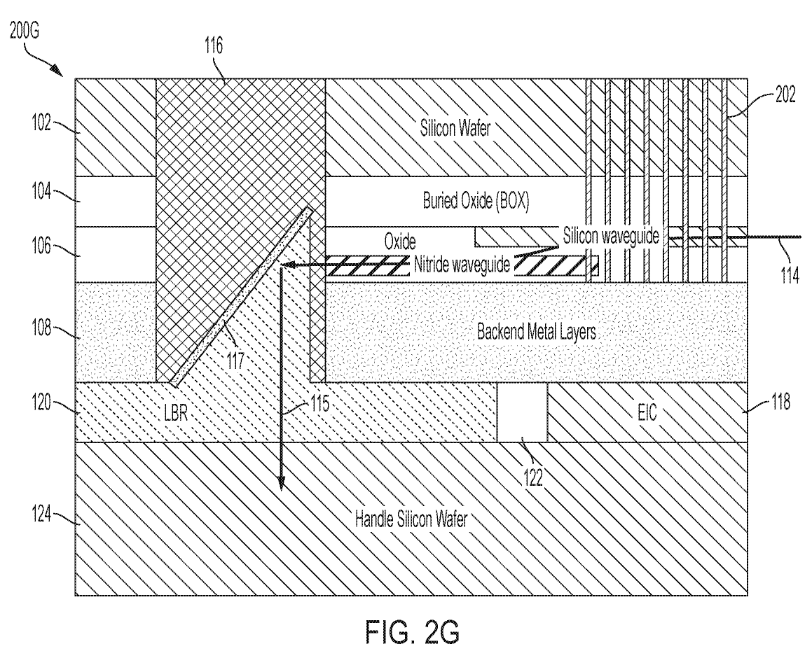

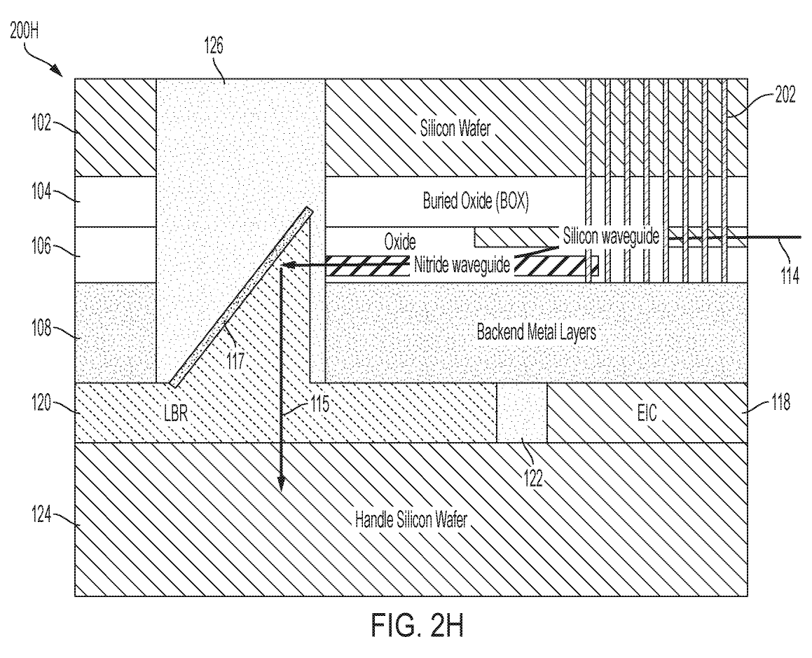

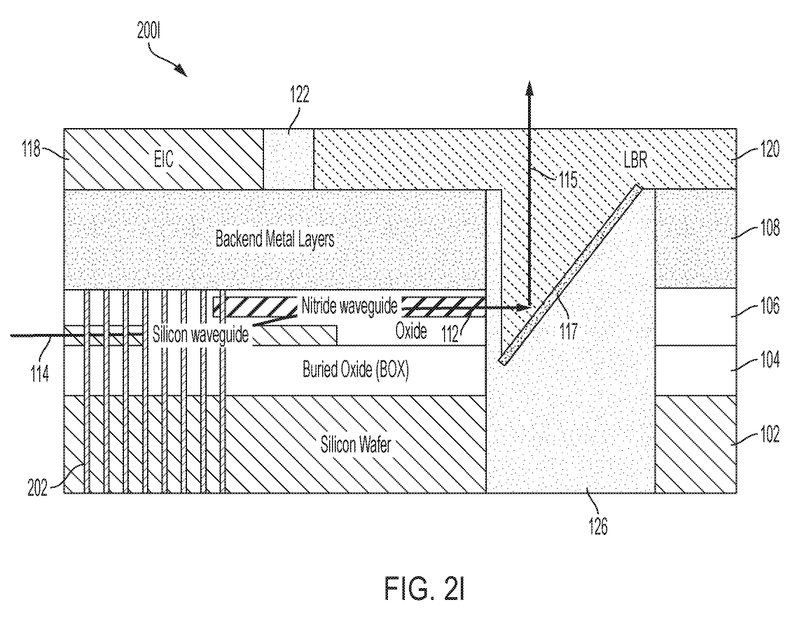

Referring now to FIGS. 2A-2I in conjunction with FIGS. 1A-1H, FIG. 2A-2I depicts a formation process for a silicon photonic device with embedded vias. FIGS. 2A-2I illustrate an alternative formation process for a silicon photonic device that incorporates additional via structures, specifically designed to enhance electrical connectivity and structural stability. While the examples corresponding to FIGS. 1A-1K focused on top-side integration with through-dielectric vias (TDVs), FIGS. 2A-2I introduce variations using through-silicon vias (TSVs), which penetrate the silicon substrate to provide direct electrical paths. This alternate approach builds upon the structures and methods discussed previously but incorporates new structural and processing operations to enable enhanced connectivity within the photonic integrated circuit (PIC). Photonic structure 200A in FIG. 2A shares several elements with photonic structure 100A described above, including similar layers and waveguide configurations. However, FIGS. 2A-2I introduces TSVs as a means to further integrate optical components with the PIC's electrical infrastructure, as detailed in the following figures.

FIG. 2A depicts a photonic structure 200A. Photonic structure 200A may be the same or similar to photonic structure 100A discussed above, wherein similarly labeled parts corresponding to similar features having similar functionality. The examples described below build upon previous devices and methods described above, and also incorporate additional structural and processing operations to enable enhanced connectivity and structural stability, particularly through the inclusion of through-dielectric vias (TDVs) and through-silicon vias (TSVs). Such features allow for advanced integration of optical components with the PIC’s electrical infrastructure.

In FIG. 2A, a process begins with silicon wafer 102, in which a cavity has been etched to include a facet. The facet may enable light to exit the nitride waveguide 112 (or alternatively a silicon waveguide 110). The cavity 116 may be created using precise etching techniques, such as DRIE or wet etching, which allow for control over the facet location and etch depth. While the figure depicts the etch stopping at the silicon wafer 102, the etch may extend into the silicon wafer 102.

In FIG. 2A, a silicon wafer 102 is provided, similar to the previous example. However, in this configuration, blind through silicon vias (TSVs) 202, may create direct electrical paths through the silicon substrate to the backend metal layers 108. The TSVs 202 may be formed by etching narrow holes through the silicon wafer 102 and filling them with a conductive material, establishing vertical connections between the backend metal layers 108 and external electronic components. This setup may support efficient electrical interfacing to the photonic integrated circuit. Additionally, a cavity 116 may be etched into the silicon wafer 102, extending down past the nitride waveguide 112. This cavity 116 may house a lower body reflector (LBR), ensuring precise light redirection within the PIC.

In FIG. 2B, the structure 200B is shown with the LBR 120 and an electronic integrated circuit (EIC) 118 hybrid bonded to the silicon wafer 102 where a portion of the LBR 120 resides within cavity 116. The hybrid or fusion bonding process may provide both mechanical stability and precise optical alignment, as well as seamless electrical integration through metal connections. The nitride waveguide 112 may be positioned to align with the LBR 120 at an angle (e.g., surface 117), optimizing light reflection and transmission within the PIC. The combination of the LBR 120 and EIC 118 may enhance the PIC's functionality by enabling both optical and electrical operations in a compact structure. The backend metal layers 108 may be implemented, providing additional connectivity options for the integrated components.

FIG. 2C illustrates the deposition of a conformal oxide layer 122 over the structure 200C. This conformal oxide layer 122 may fill remaining gaps and later allow for planarization of the surface, creating a uniform structure that may be ready for further processing. The conformal oxide layer 122 may stabilize the components thermally and mechanically.

Following the conformal oxide deposition, FIG. 2D shows for the structure 200D the planarization process where the EIC 118, conformal oxide 122 and LBR 120, may be thinned to uniform thickness. This process may prepare the surface for a handle silicon wafer to bond and invert the structure.

For the structure 200E in FIG. 2E, a handle silicon wafer 124 may be attached to the backside of the structure 200E to provide mechanical support for the remaining processing operations. The handle silicon wafer 124 may stabilize the structure as it undergoes further thinning, inversion, and oxide filling. With the handle silicon wafer 124 in place, the structure may be ready for the final modifications, such as additional etching and deposition to complete the LBR integration and other elements as well as TSV reveal of the blind TSVs formed in FIG. 2A.

Once the structure 200F is inverted, FIG. 2F shows the original silicon wafer 102 thinned for TSV reveal. In FIG. 2A, the blind TSVs may not extend to the surface of the silicon wafer 102. This operation enables revealing of these TSVs for further metallization and bumping used to enable electrical connectivity to external components.

For the structure 200G in FIG. 2G, the cavity 116 may be revealed on the backside through etching of the silicon wafer 102 selectively around the original cavity prepared in FIG. 1A. In doing so, the cavity 116 may subsequently be filled with oxide, which is used for structural, thermal and optical stability.

For the structure 200H in FIG. 2H the cavity 116 from FIG. 2G may be filled with conformal oxide 126 to avoid air gaps that could lead to poor reliability, which may be advantageous for thermal cycling, or high loss optical paths due to refractive index differences. Additionally, after the conformal oxide deposition, planarization may be used for further processing and to ensure the TSVs 202 remain revealed.

Finally, the structure 200I in FIG. 2I shows the PIC structure with integrated optical and electrical functionalities. The LBR 120 and nitride waveguide 112 create an optimized optical path, while the TSVs 202 and backend metal layers 108 provide comprehensive electrical connectivity. This example demonstrates the flexibility of using TSVs 202, allowing a thicker silicon substrate to be used for increased mechanical strength. The structure may be prepared for integration with other photonic or electronic components in complex systems, offering enhanced reliability, performance, and scalability.

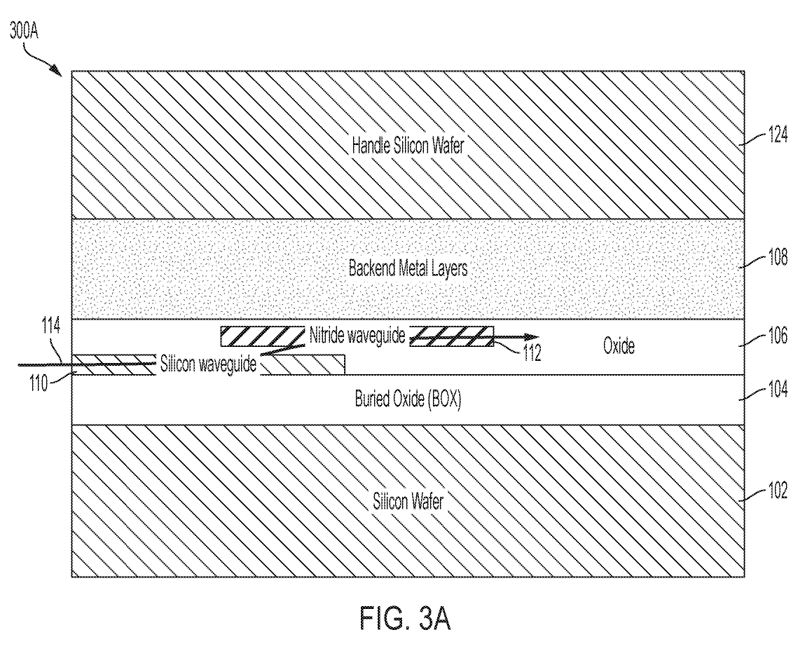

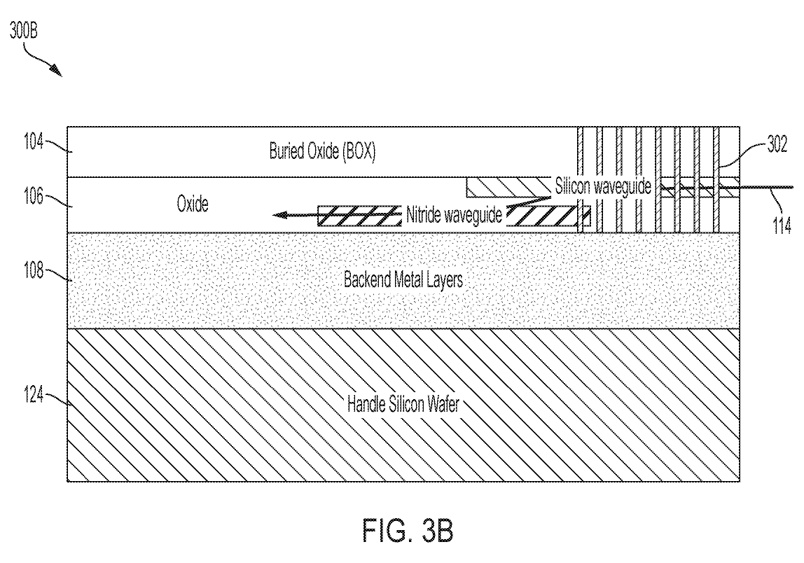

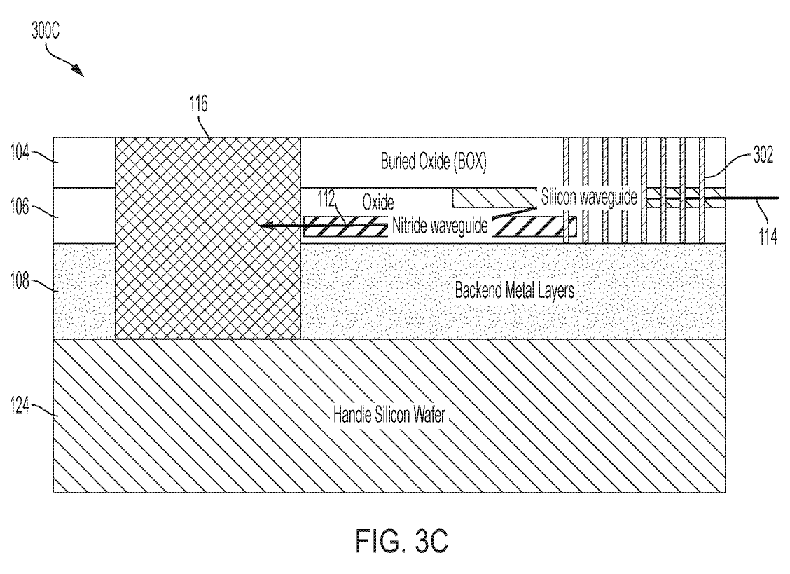

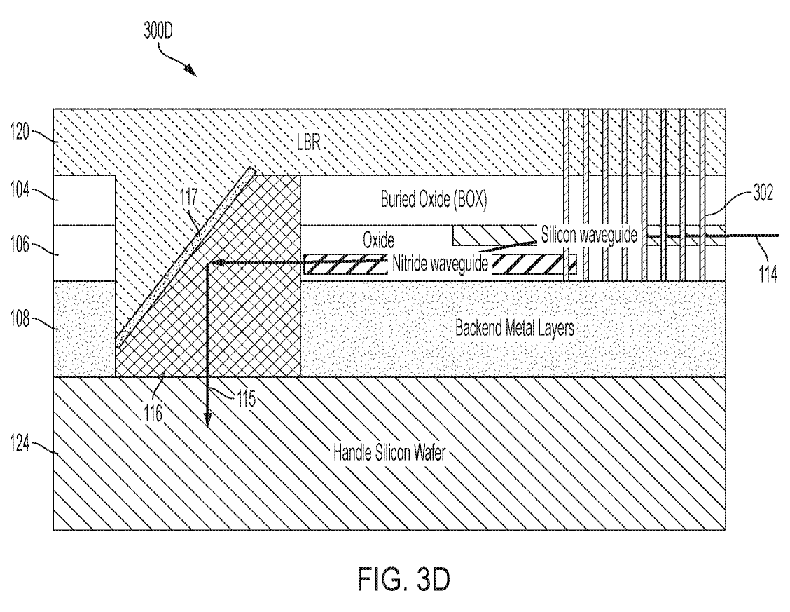

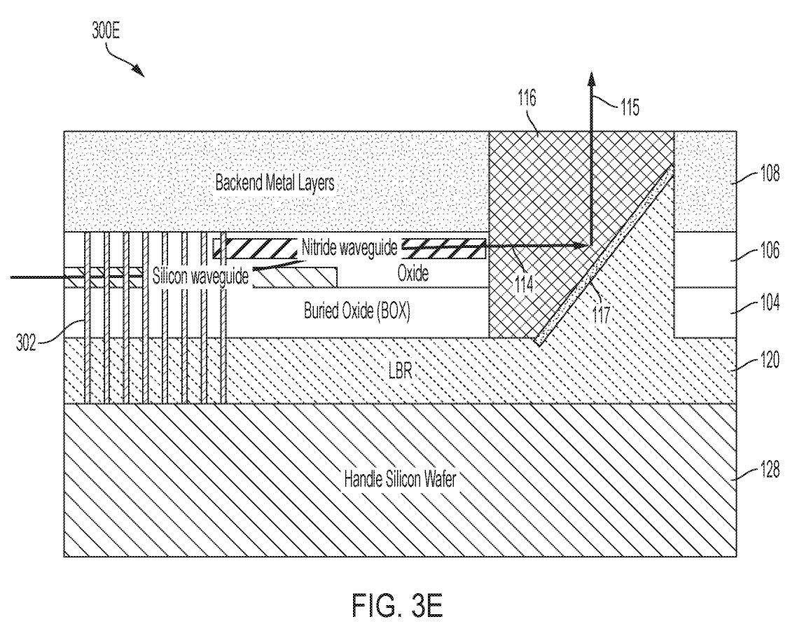

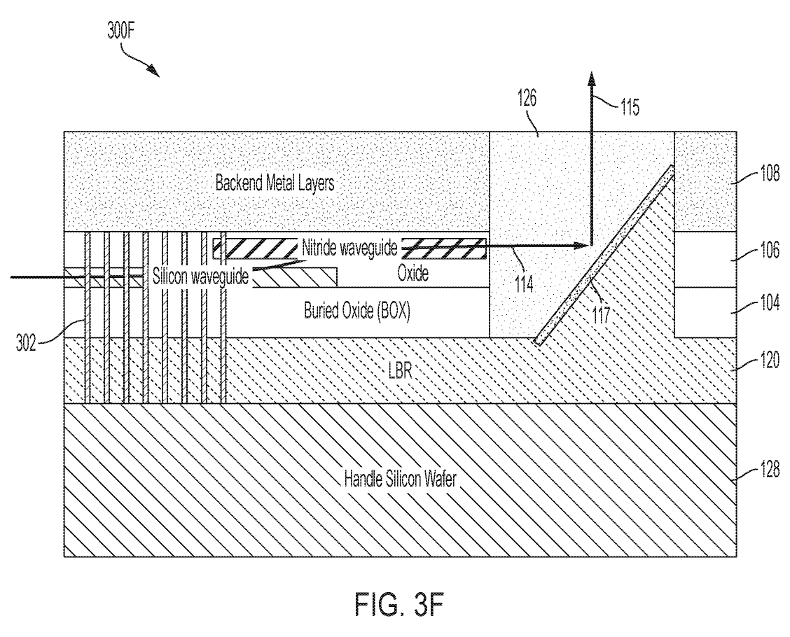

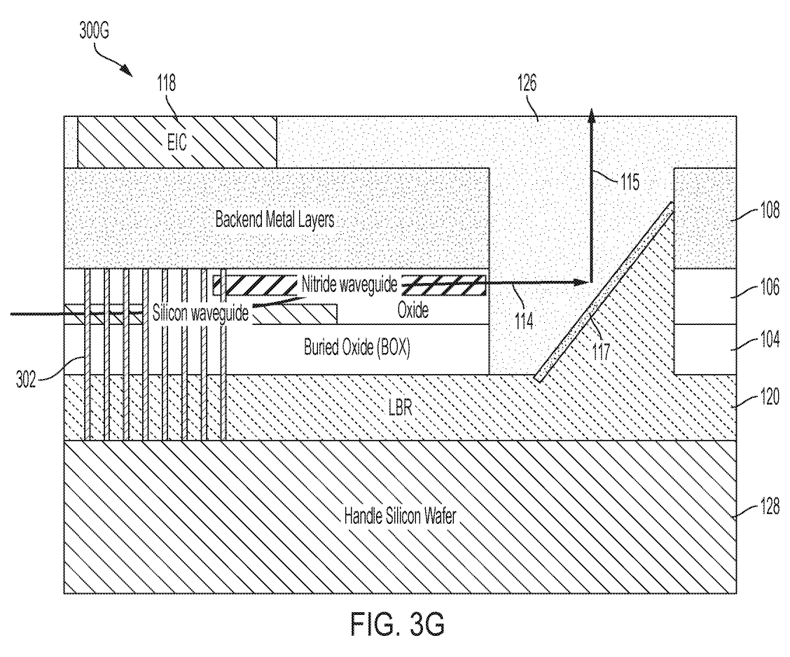

Referring now to FIGS. 3A-3G in conjunction with FIGS. 1-2, FIGS. 3A-3G, introduce a bottom-side integration process of the LBR, which differs from the previous top-side approach shown in FIGS. 1 and 2. FIG. 3A illustrates the initial operation, where a handle silicon wafer 124 may be attached to the silicon wafer 102, which may house the photonic integrated circuit (PIC) structure. This structure includes the silicon waveguide 110, nitride waveguide 112, buried oxide (BOX) layer 104, surrounding oxide 106, and backend metal layers 108. Attaching the handle silicon wafer 124 may provide mechanical support, enabling further processing from the bottom side. This alternative integration approach offers additional versatility in assembly and facilitates new configurations for advanced PIC designs.

Following attachment, structure 300A may be flipped, and the first silicon wafer layer 102 may be removed to expose the buried oxide layer 104, as illustrated in the structure 300B in FIG. 3B. Through-dielectric vias (TDVs) 302 may be created to provide pathways for electrical connectivity. These TDVs may be added early in this bottom-side integration, a departure from their position in previous options, where they were included toward the end. Additionally, the buried oxide layer 104 may be extended with an additional conformal oxide deposition and planarization prior to TDV creation. The additional thickness can enable better optical properties of the final PIC structure by reducing optical losses associated with larger modes. Larger modes are beneficial for better optical tolerances, improved optical loss and higher manufacturing yields.

For the structure 300C in FIG. 3C, a cavity 116 is etched to expose the facet of the nitride waveguide 112 (or optionally the silicon waveguide 114) from the bottom side, using a DRIE technique. This operation reorients the cavity opening, allowing access to the waveguide for optical coupling, preparing the structure for further integration.

Next, in the structure 300D in FIG. 3D, the Lower Body Reflector (LBR) 120 may be bonded onto the exposed backside of the structure through hybrid bonding. This hybrid bonding process aligns the LBR 120 with the angled reflective surface 117, enabling efficient light redirection through the cavity 116 and ensuring minimal interference. The LBR 120 may also incorporate additional TDVs and/or TSVs for enhanced electrical routing and mechanical thickness. The LBR 120 may be thinned and another wafer can be bonded for TDVs and/or TSVs as a subsequent operation. Such process might simplify the component creation and enable better electrical connection and thickness control.

Following LBR bonding, another handle silicon wafer 128 may be attached to the opposite side, as shown in the structure 300E in FIG. 3E. This handle silicon wafer 128 may be part of the original LBR wafer without need for an additional wafer. This additional support enables the structure to be flipped once more, allowing the optical path to be filled with oxide after the removal of the handle silicon wafer 128, thus providing a refractive index match to reduce optical insertion loss. In the structure 300F in FIG. 3F, the cavity and optical path may be filled with oxide to create a refractive index match that minimizes insertion loss. The oxide fill may be planarized to ready the surface for bonding with the Electrical Interface Component (EIC) 118, facilitating seamless hybrid bonding with the EIC or any other electrical component.

Finally, in the structure 300G in FIG. 3G, after EIC bonding, further conformal oxide may be deposited and the structure may be thinned and planarized to complete the transparent optical path, free of epoxy and other interference materials. This configuration ensures high optical performance and thermal resilience, readying the PIC assembly for final integration into its packaging. The design maintains a direct optical path from the waveguide through the LBR, supporting enhanced robustness and performance in thermal environments. As an alternative example, the EIC can be attached prior to the operations shown in FIG. 3A. The LBR material can be any semiconductor compatible material since the optical path does not traverse through it, while in FIGS. 1-2, the LBR bulk material was index matched to enable high optical throughput.

In some configurations, the LBR mirror surface may be comprised of dielectric stacks, metal or a combination thereof. The angle of the LBR mirror may be specified to best enable the optical path throughput and prevent any unwanted backward propagating light due to reflections.

The methods describe and/or semiconductor device 100, 200, 300 components (e.g., 102-128, 202, 302-314) as part of or apart from the photonic IC may facilitate communication with a number of processing units (e.g., xPUs), switch ASICs, memory, or other similar ASICs using off-chip communication. One or more aspects or features of the subject matter described herein can be realized in digital electronic circuitry, integrated circuitry, specially designed application specific integrated circuits (ASICs), field programmable gate arrays (FPGAs) computer hardware, firmware, software, and/or combinations thereof. These various aspects or features can include implementation in one or more computer programs that are executable and/or interpretable on a programmable system including at least one programmable processor, which can be special or general purpose, coupled to receive data and instructions from, and to transmit data and instructions to, a storage system, at least one input device, and at least one output device. The programmable system or computing system may include clients and servers. A client and server are generally remote from each other and may interact through a communication network. The relationship of client and server arises by virtue of computer programs running on the respective computers and having a client-server relationship to each other.

These computer programs, which can also be referred to programs, software, software applications, applications, components, or code, include machine instructions for a programmable processor, and can be implemented in a high-level procedural language, an object-oriented programming language, a functional programming language, a logical programming language, and/or in assembly/machine language. As used herein, the term “machine-readable medium” (or “computer readable medium”) refers to any computer program product, apparatus and/or device, such as for example magnetic discs, optical disks, memory, and Programmable Logic Devices (PLDs), used to provide machine instructions and/or data to a programmable processor, including a machine-readable medium that receives machine instructions as a machine-readable signal. The term “machine-readable signal” (or “computer readable signal”) refers to any signal used to provide non-transitory machine readable instructions and/or data to a programmable processor. The machine-readable medium can store such machine instructions non-transitorily, such as for example as would a non-transient solid-state memory or a magnetic hard drive or any equivalent storage medium. The machine-readable medium can alternatively or additionally store such machine instructions in a transient manner, such as for example as would a processor cache or other random access memory associated with one or more physical processor cores.

To provide for interaction with a user, one or more aspects or features of the subject matter described herein can be implemented on a computer having a display device, such as for example a cathode ray tube (CRT) or a liquid crystal display (LCD) or a light emitting diode (LED) monitor for displaying information to the user and a keyboard and a pointing device, such as for example a mouse or a trackball, by which the user may provide input to the computer. Other kinds of devices can be used to provide for interaction with a user as well. For example, feedback provided to the user can be any form of sensory feedback, such as for example visual feedback, auditory feedback, or tactile feedback; and input from the user may be received in any form, including, but not limited to, acoustic, speech, or tactile input. Other possible input devices include, but are not limited to, touch screens or other touch-sensitive devices such as single or multi-point resistive or capacitive trackpads, voice recognition hardware and software, optical scanners, optical pointers, digital image capture devices and associated interpretation software, and the like.

Thus, the examples described above provide an innovative and robust solution for integrating optical components within photonic integrated circuits (PICs) without the use of epoxy, overcoming the limitations associated with conventional epoxy-based approaches. By utilizing hybrid or fusion bonding techniques, strategically incorporating through-dielectric vias (TDVs) or through-silicon vias (TSVs) for electrical connectivity, and deploying both top-side and bottom-side integration processes, the examples herein achieve high-performance optical coupling and maintains structural stability under high-temperature conditions and high optical power over many wavelengths. The method and devices leverage oxide fills to optimize refractive index matching, thereby reducing insertion loss and ensuring a clear, uninterrupted optical path.

This epoxy-free integration method supports scalable, high-throughput manufacturing, making it suitable for a wide range of commercial applications, including telecommunications, data center networking, and high-speed computing. The disclosure allows for flexibility in material selection and process flow from die level assembly to wafer level assembly, enhancing compatibility with various photonic and electronic packaging. Through its advanced approach to reflector placement, waveguide coupling, and thermal resilience, this disclosure meets the increasing demands for reliability and efficiency in next-generation photonic systems. The disclosed methods and structures represent a significant advancement in the field of photonics, delivering both practical and performance benefits that are useful for modern, high-performance PIC applications.

### Examples

Example 1 includes a method for forming a photonic integrated circuit (PIC) assembly that may include providing a silicon wafer with a buried oxide layer, an optical waveguide, and backend metal layers; forming an opening in the PIC to expose a facet for light to exit the optical waveguide; and epoxy-free bonding a lower body reflector (LBR) such that a reflective surface of the LBR is placed within the opening, wherein the reflective surface is operable to direct light between the PIC and one or more external components.

Example 2 includes the method of Example 1 in which the one or more sides of the reflective surface of the LBR may include one or more of dielectric stacks or metal.

Example 3 includes the method of Example 1 further including hybrid bonding an electronic integrated circuit (EIC) to the PIC assembly; and depositing a conformal oxide layer over the silicon wafer and planarizing to form a flat surface.

Example 4 includes the method of Example 1 or Example 3, further including attaching a handle silicon wafer to provide structural support; removing the silicon wafer after hybrid or fusion bonding to expose the LBR within the opening; and depositing conformal oxide or a dielectric to fill air pockets and planarize down to a sufficient oxide thickness and refractive index for optical coupling.

Example 5 includes the method of Example 1, wherein the opening is formed by etching the backend metal and oxide layers substantially to the silicon wafer or the handle wafer or a depth into the silicon or handle wafer.

Example 6 includes the method of Example 1, further including forming through-dielectric vias (TDVs) extending through the oxide layer or through-silicon vias (TSVs) extending through the silicon wafer to provide electrical connections.

Example 7 includes the method of Example 1, wherein through-silicon vias (TSVs) or through-dielectric vias (TDVs) are created in the PIC prior to forming the opening to expose the optical waveguide facet.

Example 8 includes the method of Example 1, wherein the LBR includes one or more of through-silicon vias (TSVs), blind-TSVs, or through-dielectric vias (TDVs) prior to integration with the PIC.

Example 9 includes the method of Example 8, wherein the TSVs or blind-TSVs of the LBR are hybrid bonded onto the TDVs of the PIC.

Example 10 includes the method of Example 9, further including thinning the silicon wafer and performing a metallization operation to expose the TSVs or TDVs.

Example 11 includes the method of claim 1, wherein the bulk LBR includes a dielectric-based material with a refractive index matched to minimize optical reflections into the bulk material.

Example 12 includes a photonic integrated circuit (PIC) assembly, including: a silicon wafer having a buried oxide layer (BOX), an optical waveguide, and backend metal layers; an opening with an exposed facet enabling light to escape the optical waveguide; a lower body reflector (LBR) having a reflective surface wherein the LBR is bonded without epoxy to the surface such that the reflective surface directs light from the optical waveguide to external components.

Example 13 includes the PIC assembly of Example 12, wherein one or more sides of the reflective surface of the LBR includes one or more of dielectric stacks or metal.

Example 14 includes the PIC assembly of Example 12, further including: a conformal oxide layer deposited over the structure and planarized to create a uniform surface and/or fill air voids; and a set of electrical connections comprising through-dielectric vias (TDVs) or through-silicon vias (TSVs) configured to establish vertical electrical connectivity within the assembly.

Example 15 includes the PIC assembly of Example 12, further including: an electronic integrated circuit (EIC) hybrid bonded to the structure for additional electrical interfacing, wherein the LBR and EIC are bonded to the structure via bonding without epoxy.

Example 16 includes the PIC assembly of Example 12, further including: through-silicon vias (TSVs) or through-dielectric vias (TDVs) that are blind and are subsequently exposed on the backside following silicon wafer thinning and metallization; or the TSVs or the TDVs are further integrated with other components, such as the LBR, through hybrid bonding onto the PIC.

Example 17 includes the PIC assembly of Example 12, wherein the LBR bulk material is configured for a refractive index match to minimize optical reflections from the PIC waveguide.

Example 18 includes the PIC assembly of Example 12, further including an oxide-filled or dielectric-filled cavity within the opening, configured to minimize air gaps and minimize optical reflections to the optical waveguide.

Example 19 includes the PIC assembly of Example 18, wherein the oxide or dielectric extends the BOX layer to improve optical performance.

Example 20 includes the PIC assembly of Example 12, wherein the handle silicon wafer is attached to the structure prior to forming the opening to expose the optical waveguide facet from the backside.

The examples described herein may be embodied in systems, apparatus, methods, computer programs and/or articles depending on the configuration. Any methods or the logic flows depicted in the accompanying figures and/or described herein do not necessarily require the particular order shown, or sequential order, to achieve desirable results. The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. The implementations described above can be directed to various combinations and subcombinations of the disclosed features and/or combinations and subcombinations of further features noted above. Furthermore, above described advantages are not intended to limit the application of any issued claims to processes and structures accomplishing any or all of the advantages. Furthermore, any reference to this disclosure in general or use of the word “example” in the singular is not intended to imply any limitation on the scope of the claims set forth below. Multiple examples may be set forth according to the limitations of the multiple claims issuing from this disclosure, and such claims accordingly define the example(s) herein, and their equivalents, that are protected thereby.

In the claims, any reference signs placed between parentheses shall not be construed as limiting the claim. The word “comprising” or “including” does not exclude the presence of elements or steps other than those listed in a claim. In a device claim enumerating several means, several of these means may be embodied by one and the same item of hardware. The word “a” or “an” preceding an element does not exclude the presence of a plurality of such elements. In any device claim enumerating several means, several of these means may be embodied by one and the same item of hardware. The mere fact that certain elements are recited in mutually different dependent claims does not indicate that these elements cannot be used in combination.

Although the description provided above provides detail for the purpose of illustration based on what is currently considered to be the most practical and preferred examples, it is to be understood that such detail is solely for that purpose and that the disclosure is not limited to the expressly disclosed examples, but, on the contrary, is intended to cover modifications and equivalent arrangements that are within the spirit and scope of the appended claims. For example, it is to be understood that the present disclosure contemplates that, to the extent possible, one or more features of any example can be combined with one or more features of any other example.

1. A method for forming a photonic integrated circuit (PIC) assembly, comprising:
providing a silicon wafer with a buried oxide layer, an optical waveguide, and backend metal layers;
forming an opening in the PIC to expose a facet for light to exit the optical waveguide; and
epoxy-free bonding a lower body reflector (LBR) such that a reflective surface of the LBR is placed within the opening, wherein the reflective surface is operable to direct light between the PIC and one or more external components.

2. The method of claim 1, wherein one or more sides of the reflective surface of the LBR comprises one or more of dielectric stacks or metal.

3. The method of claim 1, further comprising
hybrid bonding an electronic integrated circuit (EIC) to the PIC assembly; and
depositing a conformal oxide layer over the silicon wafer and planarizing to form a flat surface.

4. The method of claim 1, further comprising
attaching a handle silicon wafer to provide structural support;
removing the silicon wafer after hybrid or fusion bonding to expose the LBR within the opening; and
depositing conformal oxide or a dielectric to fill air pockets and planarize down to a sufficient oxide thickness and refractive index for optical coupling.

5. The method of claim 1, wherein the opening is formed by etching the backend metal and oxide layers substantially to the silicon wafer or a handle wafer or a depth into the silicon or handle wafer.

6. The method of claim 1, further comprising forming through-dielectric vias (TDVs) extending through the oxide layer or through-silicon vias (TSVs) extending through the silicon wafer to provide electrical connections.

7. The method of claim 1, wherein through-silicon vias (TSVs) or through-dielectric vias (TDVs) are created in the PIC prior to forming the opening to expose the facet of the optical waveguide.

8. The method of claim 1, wherein the LBR comprises one or more of through-silicon vias (TSVs), blind-TSVs, or through-dielectric vias (TDVs) prior to integration with the PIC.

9. The method of claim 8, wherein the TSVs or blind-TSVs of the LBR are hybrid bonded onto the TDVs of the PIC.

10. The method of claim 9, further comprising thinning the silicon wafer and performing a metallization operation to expose the TSVs or TDVs.

11. The method of claim 1, wherein bulk material of the LBR comprises a dielectric-based material with a refractive index matched to minimize optical reflections into bulk material.

12. A photonic integrated circuit (PIC) assembly, comprising:
a silicon wafer having a buried oxide layer (BOX), an optical waveguide, and backend metal layers;
an opening with an exposed facet enabling light to escape the optical waveguide; and
a lower body reflector (LBR) having a reflective surface wherein the LBR is bonded without epoxy to the surface so that the reflective surface directs light from the optical waveguide to external components.

13. The PIC assembly of claim 12, wherein one or more sides of the reflective surface of the LBR comprises one or more of dielectric stacks or metal.

14. The PIC assembly of claim 12, further comprising:
a conformal oxide layer deposited over a structure and planarized to create a uniform surface and/or fill air voids; and
a set of electrical connections comprising through-dielectric vias (TDVs) or through-silicon vias (TSVs) operable to establish vertical electrical connectivity within the assembly.

15. The PIC assembly of claim 12, further comprising:
an electronic integrated circuit (EIC) hybrid bonded to a structure for additional electrical interfacing, wherein the LBR and EIC are bonded to the structure via bonding without epoxy.

16. The PIC assembly of claim 12, further comprising:
through-silicon vias (TSVs) or through-dielectric vias (TDVs) that are blind and are subsequently exposed on a backside following silicon wafer thinning and metallization; or
the TSVs or the TDVs are further integrated with other components, such as the LBR, through hybrid bonding onto the PIC.

17. The PIC assembly of claim 12, wherein bulk material of the LBR is configured for a refractive index match to minimize optical reflections from the PIC waveguide.

18. The PIC assembly of claim 12, further comprising an oxide-filled or dielectric-filled cavity within the opening, configured to minimize air gaps and minimize optical reflections to the optical waveguide.

19. The PIC assembly of claim 18, wherein the oxide or dielectric extends the BOX layer to improve optical performance.

20. The PIC assembly of claim 12, wherein a handle silicon wafer is attached to a structure prior to forming the opening to expose the facet of the optical waveguide from a backside.
